(19) United States
(12) Patent Application Publication
(10) Pub. No.: US 2020/0303172 A1
(43) Pub. Date: Sep. 24, 2020

(54) TARGET ASSEMBLY SHIELD

(71) Applicant: Applied Materials, Inc., Santas Clara, CA (US)

(72) Inventors: William R. Johanson, JR., Gilroy, CA (US); Keith A. Miller, Mountain View, CA (US)

(21) Appl. No.: 16/362,443

(22) Filed: Mar. 22, 2019

(51) Int. Cl. H01J 37/34

(52) U.S. Cl. CPC H01J 37/3441; H01J 37/3447; H01J 37/3435; H01J 37/3426; H01J 37/3417

(57) ABSTRACT

Embodiments described herein relate to shields for use in target assemblies in semiconductor process chambers. The shields can be used to shield exposed surfaces and chamber components within the process chambers such that unwanted redeposits are prevented from forming on the exposed surfaces and other chamber components. In some embodiments, the shields are electrically floating and are configured to cover the ends of the target. The target assembly has a target support secured to a mounting plate and a plurality of pins extending therefrom. Each of the shields has a shield body with an opening. The shield body has alignment features configured to align with the plurality pins such that the shield connects with the target support. Shields as described herein can be made of smooth edges, helping to minimize particle generation and to prevent arcing at least partially caused by sharp edges of shields.

### BACKGROUND

### Field

Embodiments described herein generally relate to semiconductor process chambers and, more particularly, to shields for use in target assemblies in semiconductor process chambers.

### Description of the Related Art

Integrated circuits (IC) may include more than one million micro-electronic devices such as transistors, capacitors, and resistors. Modern ICs are manufactured in process chambers using a multitude of steps, such as sputter deposition. Sputter deposition is a physical vapor deposition (PVD) method of thin film deposition by sputtering. This involves ejecting material from a target onto a substrate such as a silicon wafer. Sputtered atoms ejected from the target have a wide energy distribution, typically up to tens of eV. The sputtered ions can ballistically fly from the target in straight lines and impact energetically on the substrates, vacuum chamber, or in other components of the process chamber.

Sputtering is used extensively in the semiconductor industry to deposit thin films of various materials in integrated circuit processing. Thin antireflection coatings on glass for optical applications are also deposited by sputtering. Because of the low substrate temperatures used, sputtering is an ideal method to deposit contact metals for thin-film transistors. Another familiar application of sputtering is low-emissivity coatings on glass, used in double-pane window assemblies. The coating is a multilayer containing silver and metal oxides such as zinc oxide, tin oxide, or titanium dioxide.

However, due to the high energies of the sputtered ions, redeposition is an unfortunate side effect of a standard sputtering process, in which scattered sputtered ions form redeposits in areas of the chamber beside the substrate. For example, unwanted redeposits can form back onto exposed surfaces and chamber components within the process chamber. The redeposited material can spall off as particles.

Accordingly, there is a need for a way to effectively shield exposed surfaces and chamber components within a process chamber from redeposits.

### SUMMARY

One or more embodiments described herein generally relate to shields for use in target assemblies and process chambers for processing semiconductor substrates.

In one embodiment, a shield in a process chamber includes a shield body having an opening formed through a portion of the shield body, wherein the shield body has a plurality of alignment features formed therein, each of the alignment features configured to align with a pin for locating and aligning the shield, and wherein the shield body has a mounting hole formed therein and configured to secure the shield to the target assembly through one of the alignment features.

In another embodiment, a target assembly includes a mounting plate; a plurality of pins extending from the mounting plate; a target support secured to the mounting plate, the target support having a first diameter; a target supported by the target support; and a shield comprising: a shield body having an opening through a portion of the shield body, the opening having a second diameter that is larger than the first diameter, wherein the shield body has a plurality of alignment features formed therein, each of the alignment features configured to align with one of the plurality of pins such that the shield connects with the target support, and wherein the shield body has a mounting hole formed therein and configured to secure the shield to the target support through at least one of the plurality of pins.

In another embodiment, a process chamber includes a chamber body comprising a bottom wall, a top wall, and one or more side walls collectively defining a process region; an aperture plate extending from the one or more side walls, the aperture plate having an aperture therethrough; a source over the aperture plate; a movable support structure located within the process region; a plurality of target assemblies, each target assembly configured to sputter material through the aperture toward the substrate support, wherein each target assembly comprises: a mounting plate; a plurality of pins extending from the mounting plate; a target support secured to the mounting plate, the target support having a first diameter; a target supported by the target support; and a shield comprising: a shield body having an opening through a portion of the shield body, the opening having a second diameter that is larger than the first diameter, wherein the shield body has a plurality of alignment features formed therein, each of the alignment features configured to align with one of the plurality of pins such that the shield connects with the target support, and wherein the shield body has a mounting hole formed therein and is configured to secure the shield to the target support through at least one of the plurality of pins.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic side view of a process chamber for processing a semiconductor substrate according to at least one embodiment described in the present disclosure;

FIG. 2 is a schematic side view of a target assembly according to at least one embodiment described in the present disclosure;

FIG. 3 is a perspective view of a target assembly according to at least one embodiment described in the present disclosure;

FIG. 4A is a rear side view of a shield according to at least one embodiment described in the present disclosure;

FIG. 4B is a front side view of the shield shown in FIG. 4A according to at least one embodiment described in the present disclosure;

FIG. 5 is a partial perspective view of the target assembly with a shield sliding across a target according to at least one embodiment described in the present disclosure; and

FIG. 6 is a partial side view of the target assembly shown in FIG. 5 with the shield secured to the target support according to at least one embodiment described in the present disclosure.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

Embodiments described herein generally relate to shields for use in target assemblies in semiconductor process chambers. The shields can be used to shield exposed surfaces and chamber components within a process chamber such that unwanted redeposits are prevented from forming back onto the exposed surfaces and chamber components. In some embodiments, the shields are electrically floating and are configured to cover the ends of the target. The target assembly has a target support secured to a mounting plate and a plurality of pins extending from the mounting plate. Each of the shields has a shield body with an opening. The shield body has alignment features configured to align with the plurality pins such that the shield connects with the target support.

In some embodiments, the diameter of the shield body opening is larger than the diameter of the target support, assuring protection of all mechanical parts of the target assembly from redeposits. Unlike conventional shields with sharp edges, shields as described herein can be made of smooth edges, helping to minimize particle generation and to prevent arcing. The shields can be made from ceramic material, which is thermally and structurally stable along with having a closer coefficient of thermal expansion (CTE) match to anticipated deposition materials. Additionally, the shields can be serviceable and recyclable, helping save costs and prevent waste.

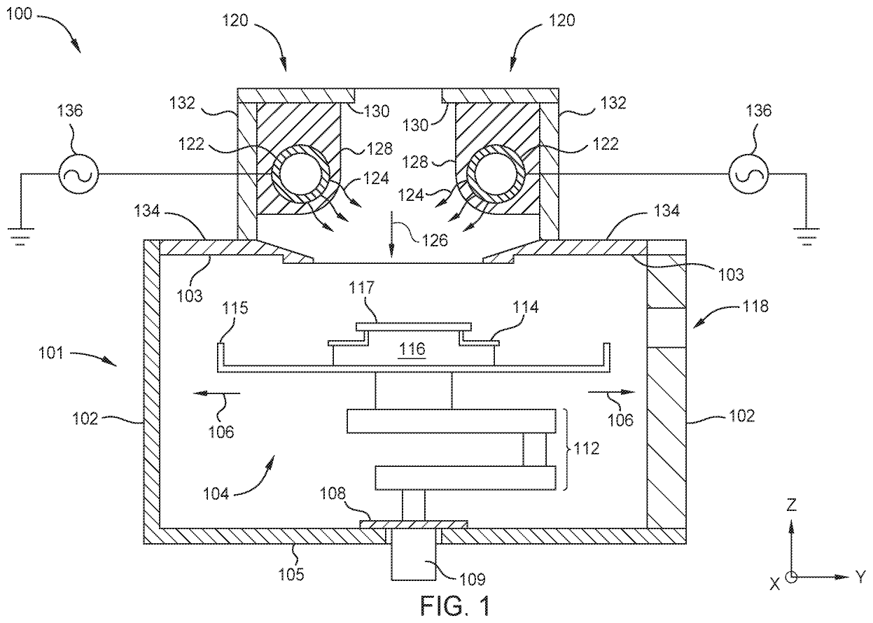

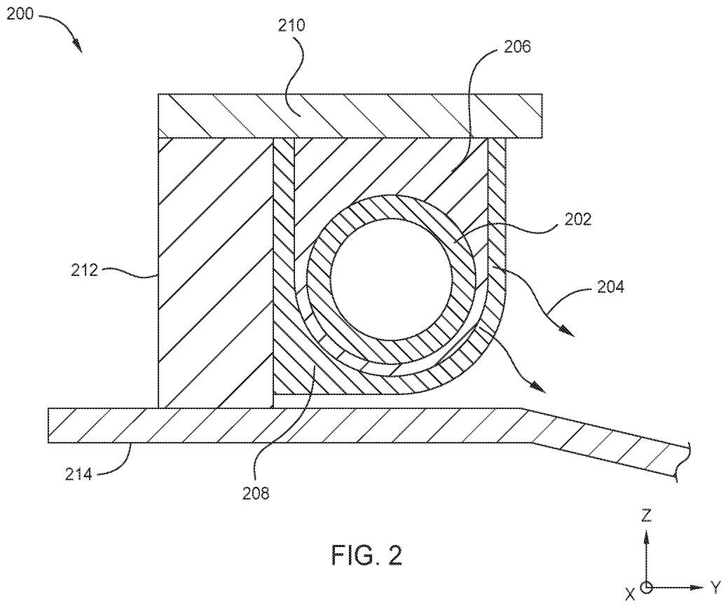

FIG. 1 is a schematic side view of a process chamber 100 for processing a semiconductor substrate according to at least one embodiment described in the present disclosure. The process chamber 100 includes a plurality of target assemblies 120 (two shown here). Each target assembly 120 includes a target 122, a shield 128, and a mounting plate 130. The shield 128 is mounted to the mounting plate 130 such that the shield 128 covers the ends of the target 122 and the target support 206 (FIG. 2). The shield 128 can also be mounted to the target support 206, which is described further below. In these embodiments, the shield 128 is electrically floating. The material of the target 122 can include a metal or a semiconductor, such as titanium (Ti), silicon (Si), or other similar materials. The target 122 includes a plurality of target magnets (not shown). The plurality of target magnets each has a fixed strength that can be different among the plurality of target magnets. In some embodiments, the plurality of target magnets are electromagnets. The powered target magnets cause sputtering of the target 122 through an electromagnetic interaction, which deposits material from the target 122 onto a substrate 117 through an aperture 126 below at a sputtering direction 124 as shown by the arrows in FIG. 1. The target 122 can be cylindrical, but can be other shapes as well. In these embodiments, the target 122 rotates which results in a more even erosion of the material from the target 122 on to the substrate 117. As shown in FIG. 1, the targets 122 can be powered by target power sources 136.

The process chamber 100 further includes a source 132. The source 132 connects each of the mounting plates 130 to an aperture plate 134 and helps protect each of the target assemblies 120 from the environment. The aperture plate 134 contains the aperture 126 into which the sputtered material is deposited. The aperture plate 134 extends from one or more side walls 102 of a chamber body 101 of the process chamber 100. The aperture plate 134 forms a portion of the top wall 103 of the chamber body 101. The chamber body 101 also includes a bottom wall 105. As such, the side walls 102, the top wall 103, and the bottom wall 105 collectively define a volume that includes a movable support structure 104.

The movable support structure 104 includes a robot actuator 109, a mounting flange 108 disposed on the bottom wall 105 of the process chamber 100, a robot arm set 112, and a halo 115. The robot actuator 109 is configured to move the mounting flange 108, and thus the robot arm set 112. The robot arm set 112 can act to move the movable support structure 104 both horizontally and vertically. The combination of the horizontal and vertical motions allows for moving the movable support structure 104 in a three-dimensional space. The robot arm set 112 supports the halo 115.

As shown, the substrate 117 can be placed on the substrate support 116. The substrate support 116 can be made of a ceramic material, stainless steel, or other suitable materials. The deposition ring 114 surrounds the substrate support 116, securing the substrate 117 to the substrate support 116. The deposition ring 114 can be a dielectric material or other suitable materials. The halo 115 at least partially surrounds the deposition ring 114. The halo 115 can be a metal, such as titanium (Ti) or stainless steel. The halo 115 can include a pattern and/or stiffening elements that reduces strain in the halo 115, such as an X or cross shape. The halo 115 prevents unwanted deposition of material on the other components of the movable support structure 104 below. In some embodiments, the substrate support 116 includes a heater (not shown), and the heater heats the substrate support 116 and the substrate 117 disposed on the substrate support 116 to temperatures between about 20 degrees Celsius and about 400 degrees Celsius. The substrate support 116 can also include an electrostatic chuck (not shown).

The movable support structure 104 is configured to move the substrate 117 from a slot 118 to near the aperture 126 for sputtering of material onto the substrate 117. The slot 118 allows for the substrate 117 to be placed easily within the process chamber 100 from outside the process chamber 100. In some embodiments, the slot 118 is not at an ideal vertical position for sputtering onto the substrate 117, and the movable support structure 104 moves the substrate 117 higher or lower than the slot 118 to begin deposition. Different areas of the substrate 117 that are not currently exposed by the aperture 126 can be reached by moving the substrate support 116 horizontally and/or vertically during deposition processes. During sputtering, the movable support structure 104 moves the substrate 117 along a movement path 106, as shown by the arrows in FIG. 1. The movement path 106 can be a smooth motion without pauses, or the movement path 106 can include portions of the path wherein the substrate support 116 is stationary for portions of the movement path. In some embodiments, the movement path 106 can be a linear movement as shown in FIG. 1. The movement path 106 can be in one direction, a back and forth direction, or containing multiple passes. In some embodiments, the movement path 106 can be a circular rotation about the aperture 126. The movement path 106 is such that the substrate support 116 is under the aperture 126 for at least a portion of the movement path 106 and is not under the aperture 126 for at least a portion of the movement path.

FIG. 2 is a schematic side view of a target assembly 200 according to at least one embodiment described in the present disclosure. The target assembly 200 can be similar to the target assemblies 120 described above in FIG. 1. In these embodiments, the target assembly 200 includes a mounting plate 210. The mounting plate 210 is mounted to a source 212. The source 212 is mounted to an aperture plate 214. A target support 206 is secured to the mounting plate 210. A target 202 is supported by the target support 206. As described above in FIG. 1, material from the target 202 is sputtered at a direction 204 as shown by the arrows in FIG. 2. A shield 208 is configured be secured to and make face to face contact with the target support 206, which will be described in more detail below.

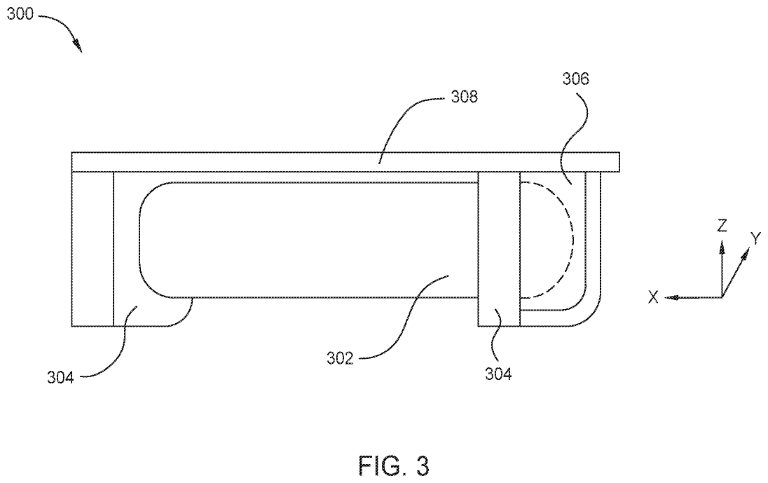

FIG. 3 is a perspective view of a target assembly 300 according to at least one embodiment described in the present disclosure. In these embodiments, two shields 304 are shown, although any number of shields can be used. The shields 304 are configured to shield each end of a target 302 from redeposits. Similar to the embodiments described above, at least one of the shields 304 is configured to be secured to the target support 306. The target support 306 is secured to a mounting plate 308.

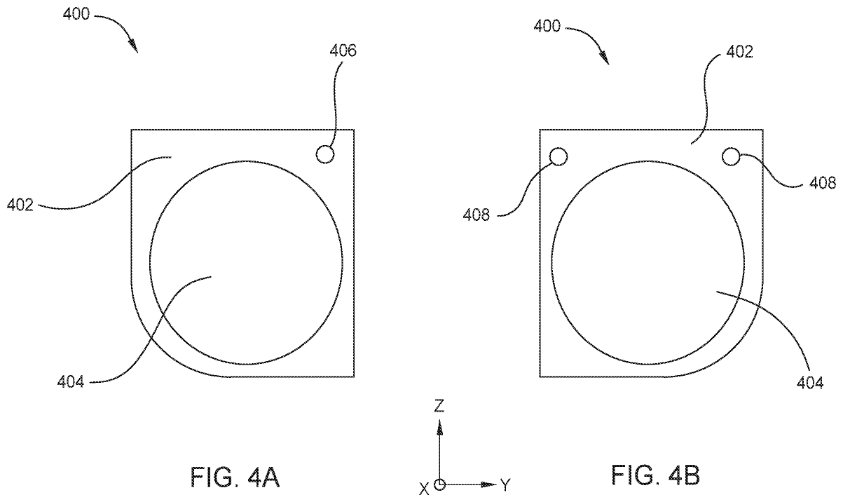

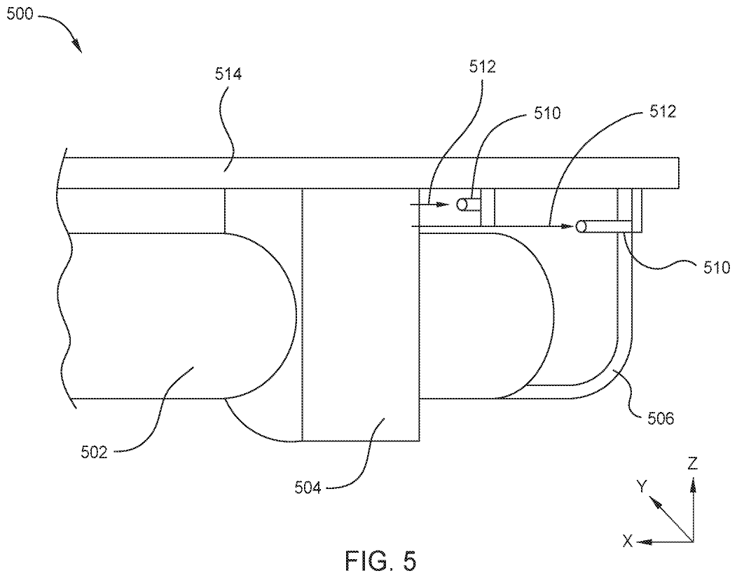

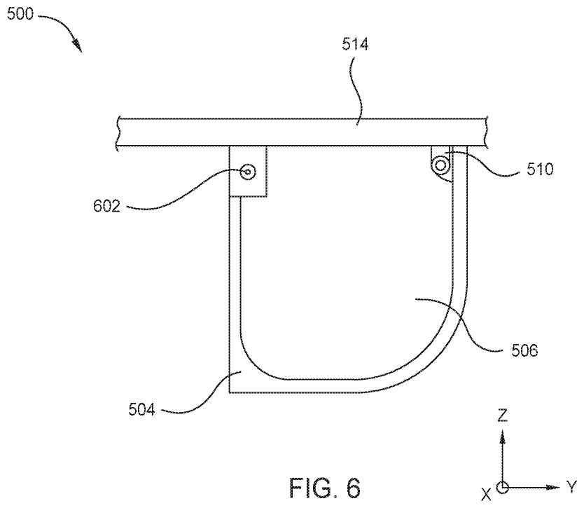

FIG. 4A is a rear side view and FIG. 4B is a front side view of a shield 400 according to at least one embodiment described in the present disclosure. The shield 400 includes a shield body 402. The shield body 402 can be made can be made of smooth edges, helping to minimize particle generation and to prevent arcing that occurs in conventional shield bodies. The shield body 402 can be made from ceramic material, which is thermally and structurally stable along with having a closer CTE match to anticipated deposition materials. In some embodiments, the surface of the shield body 402 can be texturized, grit blasted, arc sprayed, or prepared in other similar ways, which improves the adhesion of deposition of material. The shield body 402 has an opening 404 through a portion of the shield body 402. The opening 404 can be sized such that goes through a majority of the shield body 402. The shield body 402 includes a plurality of alignment features 408 and a mounting hole 406 formed therein. The alignment features 408 and the mounting hole 406 provides a configuration such that the shield 400 connects to a target support 506, which will be described in more detail in FIGS. 5 and 6 below.

FIG. 5 is a partial perspective view of the target assembly 500 with a shield 504 sliding across a target 502 according to at least one embodiment described in the present disclosure. The target assembly 500 includes a mounting plate 514. A plurality of pins 510 extend from the mounting plate 514. A target support 506 is secured to the mounting plate 514. In these embodiments, the opening 404 (FIG. 4) of the shield 504 is configured to mate with the target 502 such that the shield 504 can slide across the target 502.

In these embodiments, the shield 504 has a plurality of alignment features 408 (shown in FIG. 4) formed therein. In this embodiment, two alignment features 408 are used. Each of the alignment features 408 are configured to align with one of the plurality of pins 510 when the shield 504 slides in the direction 512 as shown by the arrows in FIG. 5. As the shield 504 continues to slide in the direction 512, the shield 504 eventually mates with the target support 506. The opening 404 has a diameter that is larger than the diameter of the target support 506. The larger diameter of the opening 404 in relation to the target support 506 provides the advantage of protecting exposed surfaces and chamber components, such as the target support 506, from redeposits forming on them.

FIG. 6 is a front side view of the target assembly 500 shown in FIG. 5 with the shield 504 secured to the target support 506 according to at least one embodiment described in the present disclosure. In these embodiments, the mounting hole 406 (FIG. 4) is configured to secure the shield 504 to the target support 506 through at least one of the plurality of pins 510 at a mounting point 602. At least another one of the plurality of pins 510 rests against the surface of the target support 506, also helping to stabilize and secure the shield 504 to the target support 506, helping to protect the exposed surfaces and chamber components from redeposits occurring from sputtering processes.

The above embodiments provide several advantages. For example, these shields help protect exposed surfaces and other chamber components from redeposits. In some embodiments, the diameter of the shield body opening is larger than the diameter of the target support, assuring protection of all mechanical parts of the process chamber from redeposits. Additionally, shields as described herein can be made of smooth edges, helping to minimize particle generation and to prevent arcing. The shields can be made from ceramic material, which is thermally and structurally stable along with having a closer CTE match to anticipated deposition materials. Furthermore, the shields can be serviceable and recyclable, helping save costs and prevent waste.

While the foregoing is directed to embodiments of the present disclosure, other and further embodiments of the disclosure may be devised without departing from the basic scope thereof, and the scope thereof is determined by the claims that follow.

1. A shield for use in a process chamber, comprising:
a shield body having an opening formed through a portion of the shield body, wherein the shield body has a plurality of alignment features formed therein, each of the alignment features configured to align with a pin for locating and aligning the shield, and wherein the shield body has a mounting hole formed therein and configured to secure the shield to a target assembly through one of the alignment features.

2. The shield of claim 1, wherein the shield body comprises smooth edges.

3. The shield of claim 1, wherein the shield body is made of a material with a coefficient of thermal expansion (CTE) match that is substantially similar to anticipated deposition materials.

4. The shield of claim 1, wherein the shield body is texturized.

5. A target assembly, comprising:
a mounting plate;
a plurality of pins extending from the mounting plate;
a target support secured to the mounting plate, the target support having a first diameter;
a target supported by the target support; and
a shield comprising:
a shield body having an opening through a portion of the shield body, the opening having a second diameter that is larger than the first diameter, wherein the shield body has a plurality of alignment features formed therein, each of the alignment features configured to align with one of the plurality of pins such that the shield connects with the target support, and wherein the shield body has a mounting hole formed therein and configured to secure the shield to the target support through at least one of the plurality of pins.

6. The target assembly of claim 5, wherein the opening is configured to mate with the target such that the shield slides across the target.

7. The target assembly of claim 6, wherein the shield is configured to slide across the target until it connects with the target support.

8. The target assembly of claim 5, wherein the mounting hole is configured to secure the shield to the target support through at least one of the plurality of pins at a mounting point.

9. The target assembly of claim 5, wherein the shield body is texturized.

10. The target assembly of claim 5, wherein the shield body comprises smooth edges.

11. The target assembly of claim 5, wherein the shield body is made of a material with a CTE match that is substantially similar to anticipated deposition materials.

12. A process chamber, comprising:
a chamber body comprising a bottom wall, a top wall, and one or more side walls collectively defining a process region;
an aperture plate extending from the one or more side walls, the aperture plate having an aperture therethrough;
a source over the aperture plate;
a movable support structure located within the process region;
a plurality of target assemblies, each target assembly configured to sputter material through the aperture toward the substrate support, wherein each target assembly comprises:
a mounting plate;
a plurality of pins extending from the mounting plate;
a target support secured to the mounting plate, the target support having a first diameter;
a target supported by the target support; and
a shield comprising:
a shield body having an opening through a portion of the shield body, the opening having a second diameter that is larger than the first diameter, wherein the shield body has a plurality of alignment features formed therein, each of the alignment features configured to align with one of the plurality of pins such that the shield connects with the target support, and wherein the shield body has a mounting hole formed therein and configured to secure the shield to the target support through at least one of the plurality of pins.

13. The process chamber of claim 12, where the plurality of target assemblies are two target assemblies.

14. The process chamber of claim 12, wherein the opening is configured to mate with the target such that the shield slides across the target.

15. The process chamber of claim 14, wherein the shield is configured to slide across the target until it connects with the target support.

16. The process chamber of claim 12, wherein the mounting hole is configured to secure the shield to the target support through at least one of the plurality of pins at a mounting point.

17. The process chamber of claim 16, wherein at least another one of the plurality of pins connects with the target support.

18. The process chamber of claim 12, wherein the shield body comprises smooth edges.

19. The process chamber of claim 12, wherein the shield body is made of a material with a CTE match that is substantially similar to anticipated deposition materials.

20. The process chamber of claim 12, wherein the shield body is texturized.
